(19) United States
(12) Patent Application Publication
(10) Pub. No.: US 2006/0278370 A1
(43) Pub. Date: Dec. 14, 2006

(54) Heat spreader for cooling electronic components

(76) Inventors: Uwe Rockenfeller, Boulder City, NV (US); Paul Sarkisian, Boulder City, NV (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/148,773

(22) Filed: Jun. 8, 2005

(51) Int. Cl. H05K 7/20

(52) U.S. Cl. 165/104.33; 361/700

(57) ABSTRACT

A unitary heat spreader for cooling electronic components comprising an evaporator section comprising a plate configured for heat exchange communication with electronic components and a plurality of elongated evaporator channels therein, and a liquid phase-change refrigerant in the evaporator channels, and first and second condenser sections configured to substantially avoid heat exchange contact with electronic components, each condenser section comprising one or more elongated condenser channels in open and continuous fluid communication with one or more of the evaporator channels.

### BACKGROUND OF THE INVENTION

Cooling of electronic circuit boards, computer chips, microprocessors, and other heat-generating components within a computer housing or case using conventional solid material heat spreaders is often inadequate. Yet, heat transfer from circuit board mounted electronic components is required to avoid reductions in operating speed caused by inadequate heat dissipation, with heat levels increasing as higher processing speeds cause chip temperatures to rise to levels which may compromise reliability and ultimately cause component failure. Modern assemblies of electronic cabinets also emphasize compactness whereby heat sink thickness is limited. Moreover, the present desire for smaller computers with less internal space for heat transfer components while using faster, higher power microprocessors further exacerbates heat dissipation problems. Although phase-change refrigerant heat exchangers provide increased cooling capacities as compared to solid material heat spreaders conventional phase-change component designs incorporate refrigerant vapor condensing towers or vertical condensation pipes which take up substantial space undesirable for compact and many portable computer applications.

### SUMMARY OF THE INVENTION

The heat spreaders described herein are configured to dissipate heat from a plurality of electronic components and comprise a plate design which takes advantage of high heat transfer rates using phase-change refrigerant heat transfer. In a preferred embodiment, the heat spreader comprises a generally flat, thin, planar evaporator plate section configured for heat exchange communication with a plurality of electronic components and one or more condenser sections, preferably opposing condenser sections on each side or at opposite ends of the evaporator plate section. The evaporator plate section is provided with a plurality of elongated evaporator channels between upper and lower plate walls having a liquid phase-change refrigerant in the evaporator channels. The condenser sections are provided with elongated condenser channels in fluid contact with the evaporator channels. A condenser section may be tubular, finned tube, finned plate or flat plate design. The condenser sections may be coplanar with the evaporator plate section or angled, bent or extend in different planes and directions from the plane of the evaporator plate section. The condenser sections are configured to avoid heat exchange contact with the electronic components, and may be configured for heat exchange contact with passive or active heat transfer components, devices or media. In one embodiment, the heat spreader is configured for direct heat exchange engagement with the plurality of electronic components. In another embodiment one or more intermediate heat conducting plates or blocks configured to engage and direct heat from one or more electronic components to the heat spreader are used.

### BRIEF DESCRIPTION OF THE DRAWINGS

FIGS. 1 and 2 illustrate different embodiments of vertical heat spreader designs having a plurality of individual evaporator and condenser channels;

FIG. 3 is a sectional view of the heat spreader of FIG. 2 taken along lines A-A;

FIG. 4 illustrates another embodiment of a vertical heat spreader design with joined evaporator and condenser channels;

FIG. 5 illustrates a horizontal heat spreader design with individual evaporator and condenser channels;

FIG. 6 illustrates a horizontal heat spreader with joined evaporator and condenser channels;

FIG. 7 is a sectional view of the heat spreader illustrated in FIG. 5 taken along lines B-B;

FIG. 8 illustrates an elliptical plate heat spreader design;

FIG. 9 schematically illustrates a heat spreader of FIG. 4 in heat exchange contact with a plurality of electronic components on a circuit board; and

FIG. 10 illustrates an intermediate heat conductive plate configured to direct heat from a plurality of electronic components to a heat spreader.

### DETAILED DESCRIPTION OF PREFERRED EMBODIMENTS

A heat spreader, as described herein, has an evaporator plate section and at least one and preferably two condenser sections. The evaporator plate and condenser sections are integrated to form a unitary heat spreader structure. The evaporator plate section is configured to receive and absorb heat from a plurality of electronic components such as computer chips, chip sets, power supply, graphics card, slot card, hard disc, microprocessor or CPU, and which components are typically installed on a circuit board, motherboard, etc. The evaporator plate section has an exterior wall surface configured for heat exchange communication with the electronic components. In one embodiment, the evaporator plate comprises an upper or first plate wall or panel and a lower or second plate wall or panel, one wall or panel configured to be positioned in direct heat exchange contact with the electronic components to be cooled or with an intermediate heat conductor. The condenser sections may be coplanar with the evaporator plate section, but are configured to avoid heat exchange contact with the electronic component to be cooled. This may be accomplished by having the condenser sections of dimensions and/or shape configured to extend beyond or directed away from the electronic component. Each condenser section is characterized by one or more elongated condenser channels in fluid contact with one or more evaporator channels. The condenser channels may be angled or pitched relative to the evaporator plate channels to assist refrigerant condensed in the condenser channels to flow gravitationally back to the evaporator channels The condenser sections may be tubular, finned tube, flat plate, or finned plates. The preferred heat spreaders shown in the drawings are designed with flat plate condenser sections. Condenser sections may be cooled by active or passive cooling means including fans, liquid cooling, heat exchangers, etc. as required or selected to meet apparatus use requirements and design limitations.

Electronic components are typically installed or positioned horizontally or vertically, although not necessarily so. For example, typical computers incorporate one or more circuit boards and/or a motherboard on which the heat generating components such as a CPU, chips or chip set and graphics card are mounted. Similarly, the heat spreaders described herein are configured to be installed and operate in a vertical or a horizontal position to cool the electronic components which are mounted on the generally horizontal or vertical circuit board. However, where the electronic components are positioned in a different plane, the heat spreader may be installed in the position to most efficiently cool the electronic components with which it is to be matched. Multiple heat spreaders may also be used.

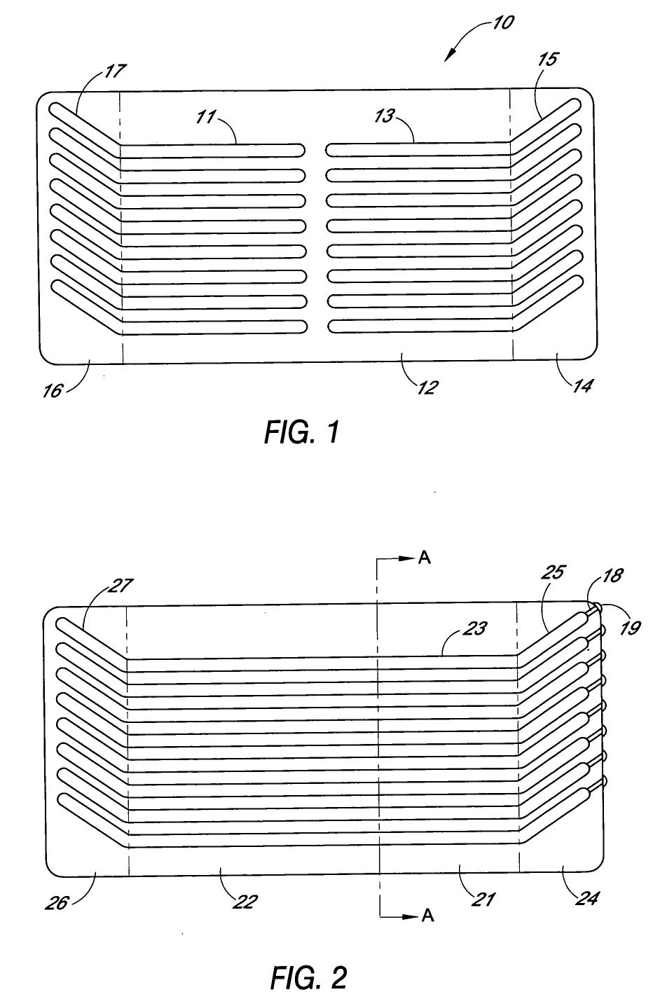

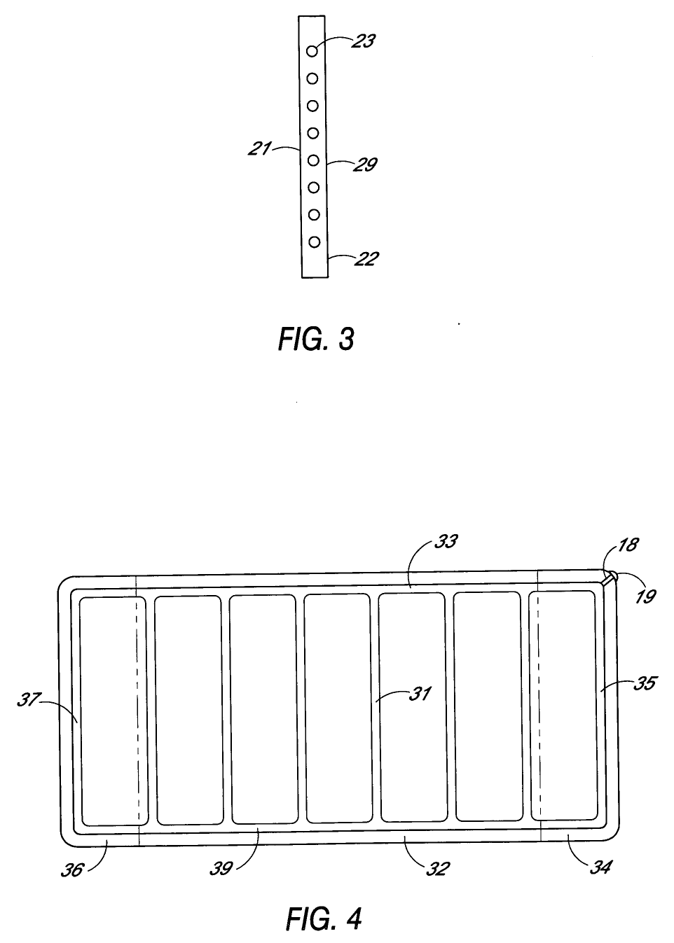

FIGS. 1-4 illustrate interior evaporator and condenser channel configurations of preferred embodiments of vertical heat spreaders. The vertical heat spreaders illustrated in FIGS. 1 and 2 utilize a plurality of individual channels in which each individual evaporator channel joining one or more condenser channels which are dedicated to provide condensation for the refrigerant with a single or individual evaporator channel. Each evaporator channel is in open and continuous fluid communication with one or more condenser channels. As illustrated in FIG. 1, a plurality of evaporator channels 11 and 13 extend along the evaporator plate section 12. Each evaporator channel on one side of the evaporator plate are joined with a single dedicated condenser channel 17 in condenser plate section 16 on that end of the evaporator plate, and on the opposite heat spreader plate end, individual evaporator channels 13 are joined with condenser channels 15 in a condenser section 14. The FIG. 2 embodiment illustrates a heat spreader plate design substantially like that shown in FIG. 1, except that the individual evaporator channels 23 are joined and extend along the entire evaporator plate section 22. In the second embodiment, condenser channels 27 within condenser plate section 26 are joined at one end of each of the evaporator channels 23, and at the opposite end, condenser channels 25 of condenser plate section 24 are open to and joined with different individual evaporator channels 23. However, not all of the evaporator channels need to be joined, and a mix of separated and joined evaporator channels may also be used. In the vertical heat embodiments, it is seen that the condenser channels can be angled or pitched relative to the horizontal evaporator channel to which they communicate to provide for gravitational flow of condensed refrigerant back to the evaporator channel.

The evaporator section of the vertical heat spreader plate is preferably generally flat, thin and substantially planar. FIG. 3, taken along lines A-A of FIG. 2, shows the evaporator plate section 22 having a front plate surface 21 and a back plate surface 29. It is the back plate surface that is to be positioned in heat exchange contact with the electronic components or against an intermediate heat conductor, although the front wall of the evaporator plate could also be used for such heat exchange contact. The elongated evaporator channels 23 are preferably substantially parallel and extend within the evaporator plate section between the front and back plate walls 21 and 29. Although parallel channels are not required, such a design allows for more channels and which are also more conveniently formed. However, other evaporator and condenser channel configurations may be used to achieve or accommodate different cooling needs. For example, evaporator channels may be spaced close together for increased cooling density in one or more areas of an evaporator section. The condenser channels shown in each respective condenser plate section are parallel. Again, different condenser channel configurations may also be used. In the embodiments illustrated in FIGS. 1 and 2, designed to be installed and operate substantially vertically, the condenser channels extend at an angle upwardly relative to the substantially horizontal evaporator channels. As such, the phase-change refrigerant fluid in the evaporator channels when heated will vaporize and flow into the condenser channels. The condenser plate sections are configured to substantially avoid contact with the heated electronic component, whereby vaporized refrigerant condenses in the cooler condenser section channels and flows back to an evaporator channel. The specific angle or pitch of the condenser channels relative to the substantial horizontal evaporator channels may be selected depending on the refrigerant used, channel size, etc., with the angles selected to optimize heat transfer rates and make efficient use of condenser channel surface area. In FIG. 2, refrigerant fluid filler pipes 18 and filler caps 19 are shown at the ends of the condenser channels on condenser plate section 24. It is to be understood that such access to the individual channels is needed for supplying refrigerant to the heat spreader, unless refrigerant is charged prior to sealing the channels at the time the heat spreader plate is manufactured or assembled.

In FIG. 4, another embodiment of a vertical heat spreader is illustrated in which the evaporator and condenser channels are joined and extend vertically rather than horizontally as described in FIGS. 1 and 2. The interior channel layout is shown as it would appear with the front panel wall removed. In evaporator plate section 32, a plurality of vertical evaporator channels 31 extend between and communicate with upper and lower evaporator channels 33 and 39. In the opposing condenser sections 34 and 36, vertical condenser channels 35 and 37 are joined to the upper and lower evaporator channels. In this embodiment, liquid refrigerant occupies a lower region of both the evaporator and condenser channels. During operation, liquid refrigerant is vaporized as it dissipates heat from the electronic components and rises in the evaporation zone channels to the upper evaporator channel 33 where it flows to condenser channels 35 and 37, becomes condensed, then accumulates in the lower condenser section and is directed into evaporator section 32 via lower evaporator channel 39. The circulation of the phase-change refrigerant in the channels as previously described is continuous and driven by heat transfer to the evaporator section and heat rejection in the condensation section. This heat spreader plate design requires only a single refrigerant charge port which may be advantageous. Although only two condensation channels 35 and 37 are illustrated, the condenser plate sections may incorporate additional condenser channels. The number of evaporator channels shown is also by way of example, and more or fewer channels may be used, depending on the size of the heat spreader, and cooling requirements including the layout and number of heat generating components to be cooled.

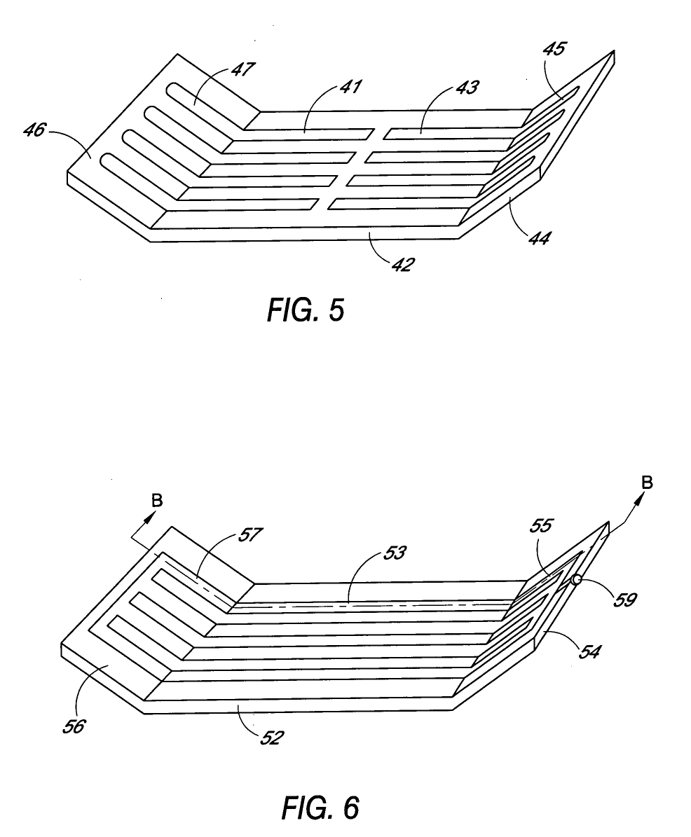

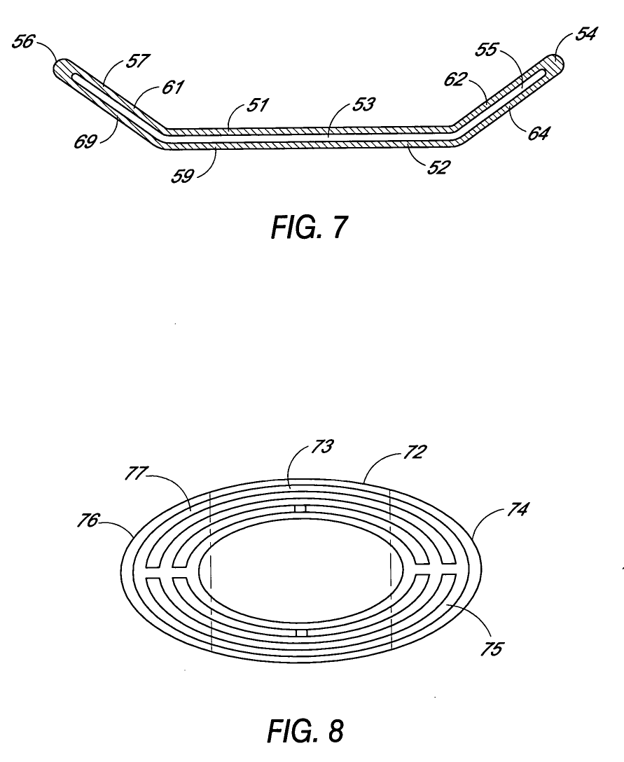

FIGS. 5 and 6 illustrate the interior channel layout embodiments of horizontal-type heat spreaders, the design of FIG. 5 using individual and separated evaporator and condenser channels and the embodiment of FIG. 6 showing the channels joined. In the horizontal heat spreader embodiments, the flat planar evaporation plate section is configured to lie substantially flat along its lower wall in heat transfer contact with the electronic components to be cooled and with condensation plate sections angled and pitched upwardly relative to a horizontal plane. FIG. 7, taken along line B-B of FIG. 6, shows generally flat, thin and planar condenser plate sections. As in the previously described embodiments, the evaporator channels and condenser channels extend along the interior of their respective sections between upper and lower plate walls. In FIG. 5, individual evaporator plate channels 41 and 43 are not connected within the evaporator plate section 42 and each of the individual evaporator channels is joined with a separate condenser channel 45, 47 in respective condenser plate sections 44 and 46. In FIG. 6, the evaporator channels 53 are joined with one another and with condenser channels 55 and 57 in condenser plate sections 54 and 56, respectively. Observing also FIG. 7, the evaporator channels 53 extend substantially horizontally between upper and lower plate walls 51 and 59 and the respective condenser channels 55 and 57 are positioned between the respective upper and lower condenser walls 62, 64 and 61, 69, respectively. In operation of the horizontal heat spreader plate embodiments, refrigerant vaporization occurs in the horizontal section channels by removing heat from the electronic components. Refrigerant vapor rises in the uplifted condenser sections which are angled to avoid heat exchange contact with the electronic components and are cooled in the cooler ambient environment causing condensation of vapor which is then returned to the evaporator section. The specific angle or pitch of the condenser sections in these generally horizontal heat spreader embodiments may be along planes between 0° and 90° relative to horizontal, or in some cases at obtuse angles greater than 90° as long as return of condensed refrigerant is provided. Again, as discussed in the embodiments of FIGS. 1 and 2, the specific angles may be determined and selected depending on the size of the channels, the refrigerant used, as well as the vertical space restrictions in which the heat spreaders are installed.

FIG. 8 illustrates yet another embodiment showing an elliptical shape heat spreader design. The condenser section channels are joined as are different ones of the evaporator section channels. The elliptical shape design illustrated is configured to operate in a horizontal position as previously described with horizontal evaporator plate section 72 housing elongated horizontal evaporator channel 73 communicating with condenser channels 75 and 77 in condenser sections 74 and 76, respectively. Accordingly, the specific exterior shape of the generally flat, thin and planar heat spreader, as described above, may be configured in other shapes depending on the layout of the electronic components it is designed to cool. Moreover, the evaporator and condenser channels need not be parallel or evenly spaced, but may be configured to best maximize cooling within the spatial conditions the heat spreader is to operate.

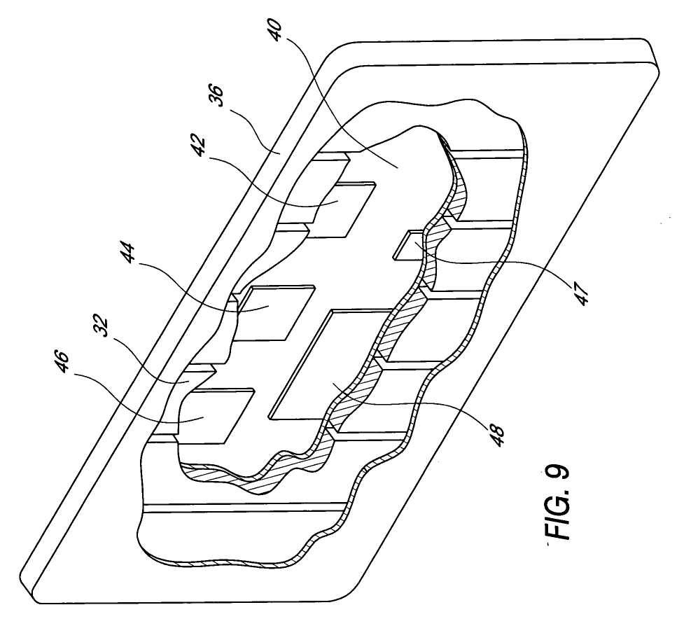

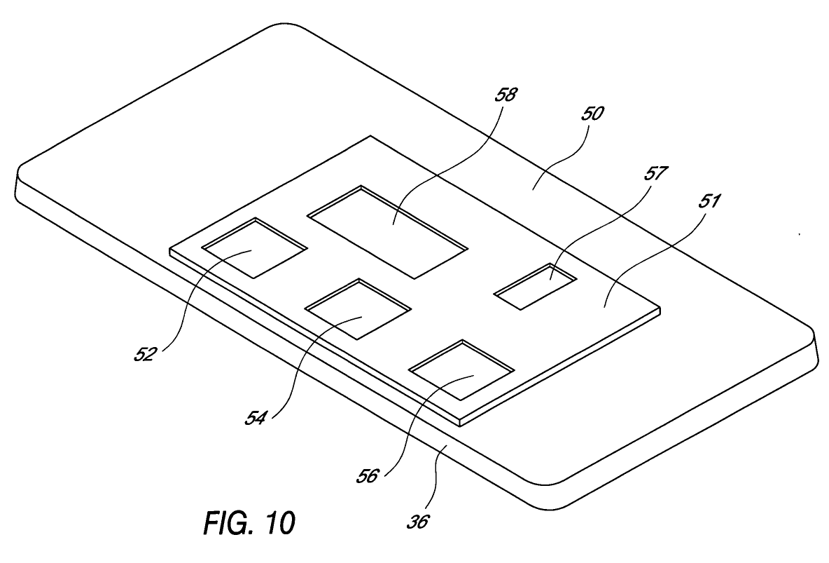

FIG. 9 schematically illustrates a location or placement and use of vertical heat spreader of the configuration shown in FIG. 4 positioned in heat exchange communication with a plurality of heat generating electronic components on a circuit board. In the drawing, the front panel wall is partially cutaway to expose interior evaporator and condenser channels. The back panel wall facing and in heat exchange communication with electronic components is also partially cutaway to show an example of a layout of components on a circuit board to be cooled. As shown, heat spreader 36 is positioned relative to circuit board 40 whereby the evaporator plate section 32 is in heat exchange contact with heat generating electronic components: chip set components 42, 44 and 46, graphics card 47 and CPU 48, the principle heat producing components. The specific heat generating components illustrated as well as the specific layout or positioning of the components on the circuit board is by way of example and for the purpose of illustration only. The circuit board design may be ATX, BTX or other design or configuration. The evaporator plate portion of the heat spreader is positioned in heat exchange contact with the heat generating components with the condenser sections 34 of the heat spreader substantially avoiding heat exchange contact with the electronic components. Again, the specific embodiment of the heat spreader of FIG. 4 is by way of example only and any heat spreader embodiment may be used and positioned to cool the electronic components as described.

The heat exchange interface or contact of the evaporator section of the heat spreader with the electronic components may be of any contour, shape or other configuration preferably to optimize heat transfer and to efficiently direct heat from the electronic components to the evaporator section. In one embodiment, a surface of the evaporator section is configured for direct heat exchange interface with the electronic components. Thus, the exterior evaporator panel surface itself may be contoured, shaped or otherwise configured for direct contact with multiple components. For example, the back panel evaporator plate section surface may be customized to specifically accommodate the shape, profile and contour of the electronic components and/or one or more intermediate heat conducting (heat transfer) plates. Such shape or contour may include machined, molded or otherwise formed depressions, cavities and the like of dimensions preferably configured for improved heat transfer efficiency between the heat spreader surface and the different electronic components simultaneously contacted by the heat spreader surface.

Where customized or specific heat spreader surface designs or configurations are impractical or otherwise unavailable, or where universal heat spreader surface configurations are desired, one or more intermediate thermally conductive plates, blocks or spacers of suitable size/shape and configuration may be placed between the surface of the evaporator plate section panel and the electronic components. FIG. 10 illustrates the use of an intermediate plate designed and configured to contact a plurality of heat generating components and direct the heat to an exterior surface of an evaporator section of a heat spreader. In the example shown, heat spreader 36 having a generally flat evaporator plate surface 50 is provided with a thin intermediate heat conductive plate 51 on which are formed a plurality of depressions having shaped concave cavities configured to receive and/or engage the different electronic components mounted on the circuit board 40 shown in FIG. 9. In the illustrated embodiment the surface of heat conductive intermediate plate 51 to face and contact electronic components is provided with depressions 52, 54 and 56 configured for receiving chips 42, 44 and 46, respectively, and depressions 57 and 58 formed to receive electronic components 47 and 48, respectively. The surfaces within the various depressions are also preferably shaped and configured to contact the respective components and efficiently transfer heat to the intermediate plate. The opposite surface of plate 51 is substantially flat or otherwise configured to rest against the substantially flat or otherwise configured surface for heat exchange contact with the facing surface of the evaporator section of heat spreader 36. The use of such an intermediate heat conducting plate having one surface configured for heat exchange contact with the electronic components and the opposite surface for heat exchange contact with a heat spreader provides for the use of a generic or universal heat spreader with a variety of different electronic components and with different component layout patterns, elevation profiles, and configurations by simply providing one or more suitably configured intermediate heat conductive plates. Although a single intermediate plate is illustrated in the example shown in FIG. 10, a plurality of plates and/or blocks having desired surface patterns or configurations as well as different and/or varying thickness to accommodate different electronic components or combinations of components may be used. For example, one intermediate plate could be configured to match a CPU, one plate to match one or more chips, etc. Such combination of intermediate plates or blocks to be used with different computer component layouts allows a generic or standardized heat spreader design to be used for cooling a variety of different computers and different component layouts and configurations and at substantially reduced manufacturing and assembly costs. Again, the shapes and configurations of the heat spreader and intermediate plate surfaces as well as the electronic components described and shown herein are by way of example only.

The material of which the phase-change heat spreader is made is a thermally conductive metallic material, such as aluminum or copper, as well as alloys or compositions containing such metals having high thermal conductivity. Examples of preferred materials include aluminum, gold, silver, titanium, copper, nickel, cupro-nickel, steel and alloys of the aforesaid or thermally conductive carbons or plastics. The channels may be formed by drilling, machining, stamping, milling, molding, or by other suitable means. For example, the heat spreader may comprise multiple plates which have been sealed by braising, welding or other methods known to those skilled in the art. The heat spreader plates may also be machined or otherwise shaped in contour plates and plate surfaces that match the contour and shape of the electronic components and preferably to provide good thermal contact with at least the most important electronic components to be cooled. Alternatively, the heat spreader plates could be mass produced in nominal sizes and contour plates added as an attachment.

The shape of any evaporator or condenser channel is not critical but rectangular, square or round channels are most practical. The channel diameters or cross-sectional dimensions between about 0.02 inch and about 0.5 inch are most practical for the electronic cooling applications. Specific channel sizes may be selected depending on the sonic, flooding, fluid transport and film boiling limits, and thus are a function of the vapor and liquid thermal dynamic and fluid transport properties of the refrigerant charge as well as the heat transfer load requirements. Multiple channels may be separated as needed depending on the size and shape of the heat spreader and the thermal load to be handled. A pitch of between about 0.25 and about 10 channels per inch is preferred. As previously described, spacing between the channels may be uniform, or not, depending on cooling density requirements. The maximum size of any channel or channel length may be limited by proper surface wetting, understanding that extreme tilt or angle of the channels may result in dry spots or areas not covered by refrigerant for desirable evaporation and condensation. It may be desirable to incorporate a wick or surface condition within the evaporator and condenser channels that allows capillary transport of liquid during operation. Such a wick or surface condition may assist and improve liquid return and further allow liquid transport against gravity force. Such design or components may be of particular relevance in mobile systems, such as vehicles, aircraft, ships, missiles, etc. in countering g forces, or lack thereof. If wicks are used, it may be important to maintain sufficient vapor space to prevent the wick from significantly obstructing the cross-section of the channels and negatively affecting the refrigerant flow. The overall heat spreader size may be between about 1 in² and about 500 in², again depending on the size and shape of the electronic component layout as well as the aforesaid load and other conditions. Again, the heat spreader may be configured to cool a plurality of electronic components, preferably between two and ten components, installed on a circuit board.

Preferred refrigerants are HFC's, CFC's, HCFC's, water, alcohol, ammonia, aqueous solutions and other suitable liquid/vapor phase-change materials. The specific refrigerant selection is dependent on thermodynamic and transport properties, operating pressure and heat transfer coefficients desired. The heat spreader housing or plate materials of construction must be compatible with the charge refrigerants and must be of sufficient thickness for pressure containment. During operation, typical fluid temperatures in the heat spreader are expected to be between about 25° C. and about 75° C, although in some applications fluid temperatures may be as high as about 150° C. The heat spreaders are expected to operate in local ambient conditions of between about −50° C. and about 100° C.

Although refrigerant charging ports are illustrated in some figures, it is to be understood that any heat spreader will require suitable charging ports, caps, etc. needed to access the channels for charging with the proper amount of refrigerant, unless charging is accomplished at the time the device is manufactured and prior to sealing of the plurality of channels. Moreover, although the heat spreader shown and described herein is intended to dissipate heat from a plurality of electronic components, it could be configured and installed to cool a single component.

The heat spreader embodiments described herein may be used for any electronic cooling environment. However, the relatively flat plate design may be of special advantage in small computer or electronics products such as laptops or other relatively thin case designs where interior space for the plurality of heat generating components is quite confined and air flow or fan capacity is very limited. In special computers and electronics designed with sealed interiors, the use of such heat spreaders for heat dissipation of multiple electronic components may also be of special interest.

What is claimed is:

1. A unitary heat spreader comprising:
an evaporator section comprising an evaporator plate configured for heat exchange communication with a plurality of electronic components and a plurality of elongated evaporator channels therein, and a liquid phase-change refrigerant in said evaporator channels; and
first and second condenser sections configured to substantially avoid heat exchange contact with an electronic component, each said condenser section comprising one or more elongated condenser channels in open and continuous fluid communication with one or more of said evaporator channels.

2. A heat spreader of claim 1 wherein said evaporator plate comprises an exterior wall surface configured for said heat exchange communication.

3. A heat spreader of claim 1 wherein said evaporator plate comprises a first panel having an exterior surface configured for said heat exchange communication and a second panel, and wherein said plurality of elongated evaporator channels extend along said plate between said first and said second panels.

4. A heat spreader of claim 1 wherein said evaporator section comprises a generally flat plate.

5. A heat spreader of claim 4 wherein said evaporator section comprises an exterior wall surface configured for said heat exchange communication.

6. A heat spreader of claim 5 wherein said exterior wall surface is contoured to engage two or more of said electronic components.

7. An assembly comprising a heat spreader of claim 5 and one or more heat conducting plates each having a first surface for engaging said exterior wall surface of said evaporator section and a second surface for engaging one or more of said electronic components.

8. An assembly of claim 7 wherein said second surface is contoured for engaging said one or more of said electronic components.

9. An assembly of claim 7 wherein said second surface is contoured for engaging a plurality of said electronic components.

10. An assembly of claim 8 wherein said exterior wall surface of said evaporator section and said first surface are substantially flat.

11. A heat spreader of claim 4 wherein said first and second condenser sections comprise generally flat plates.

12. A heat spreader of claim 11 wherein said evaporator section is generally planar along a first plane and said condenser sections are generally planar along second and third planes, respectively.

13. A heat spreader of claim 12 wherein said second and third planes are between 0° and 90° relative to said first plane.

14. A heat spreader of claim 1 wherein said evaporator section is substantially planar along a first plane and said condenser sections are substantially planar along second and third planes, respectively.

15. A heat spreader of claim 14 wherein said second and third planes are between 0° and 90° relative to said first plane.

16. A heat spreader of claim 1 wherein two or more of said evaporator channels are joined.

17. A heat spreader of claim 3 wherein two or more of said evaporator channels are joined.

18. A heat spreader of claim 1 comprising a plurality of said condenser channels.

19. A heat spreader of claim 3 comprising a plurality of said condenser channels.

20. A heat spreader of claim 18 wherein two or more of said condenser channels are joined.

21. A heat spreader of claim 13 wherein one or more of said condenser channels are joined.

22. A heat spreader of claim 19 wherein two or more of said evaporator channels are joined, and/or two or more of said condenser channels are joined.

23. A heat spreader of claim 1 comprising a thin, planar plate and wherein said elongated evaporator channels are substantially straight and substantially parallel in a first direction, and further comprising a plurality of substantially straight condenser channels in said first and second condenser and extending in directions angled relative to said first direction.

24. A heat spreader of claim 23 wherein said evaporator section comprises an exterior wall surface configured for said heat exchange communication.

25. A heat spreader of claim 24 wherein said exterior wall surface is contoured to engage two or more of said electronic components.

26. An assembly comprising a heat spreader of claim 24 and one or more heat conducting plates each having a first surface for engaging said exterior wall surface of said evaporator section and a second surface for engaging one or more of said electronic components.

27. An assembly of claim 26 wherein said second surface is contoured for engaging said one or more of said electronic components.

28. An assembly of claim 26 wherein said second surface is contoured for engaging a plurality of said electronic components.

29. An assembly of claim 27 wherein said exterior wall surface of said evaporator section and said first surface are substantially flat.

30. A heat spreader of claim 23 wherein said elongated condenser channels in said first condenser are substantially parallel in a second direction and said elongated condenser channels in said second condenser are substantially parallel in a third direction.

31. A heat spreader of claim 30 wherein said second direction and said third direction are of acute angles relative to said first direction.

32. A heat spreader of claim 31 wherein each of said evaporator channels is in fluid spreader with a single condenser channel.

33. A heat spreader of claim 31 wherein said acute angles are substantially the same.

34. A heat spreader of claim 31 wherein said acute angles are substantially the same.

35. A heat spreader of claim 1 wherein said evaporator section comprises a generally flat, thin, planar plate and wherein said first and second condenser sections comprise generally flat, thin, planar condenser plates angled relative to said evaporator plate.

36. A heat spreader of claim 35 wherein said evaporator section comprises an exterior wall surface configured for said heat exchange communication.

37. A heat spreader of claim 36 wherein said exterior wall surface is contoured to engage two or more of said electronic components.

38. An assembly comprising a heat spreader of claim 36 and one or more heat conducting plates each having a first surface for engaging said exterior wall surface of said evaporator section and a second surface for engaging one or more of said electronic components.

39. An assembly of claim 38 wherein said second surface is contoured for engaging said one or more of said electronic components.

40. An assembly of claim 38 wherein said second surface is contoured for engaging a plurality of said electronic components.

41. An assembly of claim 39 wherein said exterior wall surface of said evaporator section and said first surface are substantially flat.

42. A heat spreader of claim 35 wherein said elongated evaporator channels are substantially straight and substantially parallel in a first direction and comprising a plurality of substantially straight condenser channels extending at directions angled relative to said first direction.

43. A heat spreader of claim 42 wherein said elongated condenser channels in said first condenser are substantially parallel in a second direction and said elongated condenser channels in said second condenser are substantially parallel in a third direction.

44. A heat spreader of claim 43 wherein said second direction and said third direction are at acute angles relative to said first direction.

45. A heat spreader of claim 44 wherein each of said evaporator channels is in fluid communication with a single condenser channel.

46. A heat spreader of claim 45 wherein said acute angles are substantially the same.

47. A heat spreader of claim 43 wherein two or more of said evaporator channels are joined, and/or two or more of said condenser channels are formed.

48. A heat spreader of claim 1 wherein said evaporator section plate is configured for heat exchange communication with two to ten electronic components.

49. A heat spreader of claim 3 wherein said evaporator section plate is configured for heat exchange communication with two to ten electronic components.

50. A heat spreader of claim 7 wherein said evaporator section plate is configured for heat exchange communication with two to ten electronic components.

51. A unitary heat spreader comprising:
an evaporator section comprising an evaporator plate configured for heat exchange communication with an electronic component having a plurality of elongated evaporator channels therein, and a liquid phase-change refrigerant in said evaporator channels; and
first and second condenser sections configured to substantially avoid heat exchange contact with an electronic component, each said condenser section comprising one or more elongated condenser channels in open and continuous fluid communication with one or more of said evaporator channels.
